(19) United States
(12) Patent Application Publication
(10) Pub. No.: US 2018/0277422 A1
(43) Pub. Date: Sep. 27, 2018

(54) BONDED WAFER PRODUCTION METHOD AND BONDED WAFER

(71) Applicant: SHIN-ETSU HANDOTAI CO., LTD., Tokyo (JP)

(72) Inventors: Toru ISHIZUKA, Takasaki-shi (JP); Norimichi TANAKA, Annaka-shi (JP)

(73) Assignee: SHIN-ETSU HANDOTAI CO., LTD., Tokyo (JP)

(21) Appl. No.: 15/904,850

(22) Filed: Feb. 26, 2018

(30) Foreign Application Priority Data
Mar. 27, 2017 (JP) 2017-60757

(51) Int. Cl. H01L 21/762; G01L 9/00; B28D 1/00; H01L 21/02; H01L 21/20; H01L 33/00

(52) U.S. Cl. CPC H01L 21/76254; G01L 9/0042; B28D 1/005; H01L 33/0079; H01L 21/02052; H01L 21/2007; H01L 21/76243

(57) ABSTRACT

A bonded wafer production method for producing a bonded wafer having a thin film on a base wafer by forming an ion implanted layer in a bond wafer by implanting at least one of gas ion of a hydrogen ion and a rare gas ion from a surface of the bond wafer and, after directly bonding an ion implanted surface of the bond wafer and a surface of the base wafer together or bonding the ion implanted surface of the bond wafer and the surface of the base wafer together with an insulator film placed therebetween, delaminating the bond wafer at the ion implanted layer, wherein, as at least one of the bond wafer and the base wafer, an epitaxial wafer is used, and, as cleaning of the epitaxial wafer which is performed before the formation of an epitaxial layer, single wafer processing spin cleaning is performed.

### BACKGROUND OF THE INVENTION

### Technical Field

The present invention relates to a bonded wafer production method and a bonded wafer.

### Background Art

As a method for producing an SOI wafer, in particular, a method for producing a thin-film SOI wafer that can enhance the performance of a leading-edge integrated circuit, a method for producing an SOI wafer by delaminating an ion implanted wafer after bonding (an ion implantation delamination method: the technology also called SmartCut® process) has attracted attention. This ion implantation delamination method is the technology of obtaining an SOI wafer by forming an insulator film (in particular, an oxide film) on at least one of two silicon wafers and implanting gas ions such as hydrogen ions or rare gas ions from the upper surface of one silicon wafer (a bond wafer) and thereby forming a microbubble layer (an encapsulation layer) in the wafer, then bringing the surface in which the ions are implanted into close contact with (bonding the surface to) the other silicon wafer (a base wafer) via the insulator film (in particular, the oxide film) placed therebetween, then delaminating the one wafer (the bond wafer) in the form of a thin film by using the microbubble layer as a cleaved plane by performing heat treatment (delamination heat treatment), and achieving firm bonding by performing another heat treatment (bonding heat treatment) (refer to Patent Document 1). At this stage, the cleaved plane (the delaminated plane) is the surface of an SOI layer, and an SOI wafer whose SOI film thickness is small and has a high degree of uniformity is obtained with relative ease.

In the past, a base wafer of a bonded SOI wafer was a substrate for supporting an SOI layer as a support substrate; in recent years, however, there has been an increase in the number of cases in which even a foundation of a buried insulator film layer (in particular, a buried oxide film layer called a BOX layer) is separated by a trench or the like and used as part of a device structure. As one of the methods of forming such a region which is used as part of a device structure, a wafer (an epitaxial wafer) in which an epitaxial layer is formed by controlling dopants is fabricated, and an SOI wafer using this wafer as a base wafer has been produced.

Moreover, also in a directly bonded wafer which is fabricated by bonding wafers together without an insulator film, there is a case in which an epitaxial wafer is used as a raw material wafer to be bonded (at least one of a bond wafer and a base wafer).

In both of the case in which a bond wafer and a base wafer are bonded together with an insulator film placed therebetween and the case in which a bond wafer and a base wafer are directly bonded together, a region called a terrace portion is present in a bonded wafer obtained by delaminating the bond wafer in the form of a thin film. This terrace portion is a region in which a thin film is not present on the base wafer. This is caused by the following reason: on the periphery of each of two wafers to be bonded together, a portion, which is called a polishing sag, whose thickness is slightly reduced or a chamfered portion is present and the portions are not bonded together by bonding or remain as unbonded portions having weak bonding strength.

### CITATION LIST

### Patent Literature

Patent Document 1: Japanese Unexamined Patent Publication (Kokai) No. H5-211128

Patent Document 2: Japanese Unexamined Patent Publication (Kokai) No. 2013-4760

Patent Document 3: Japanese Unexamined Patent Publication (Kokai) No. 2006-270039

### SUMMARY OF THE INVENTION

### Technical Problem

In a bonded wafer in which an epitaxial wafer is used as a raw material wafer as described above, a portion in which, in some regions thereof, the width (terrace width) of a terrace portion after delamination of a bond wafer in the form of a thin film is larger than the terrace width in the other regions undesirably appears.

The present invention has been made to solve the above problem and an object thereof is to provide a bonded wafer production method that can produce a bonded wafer with a small terrace width when an epitaxial wafer is used as a bond wafer or a base wafer.

### Solution to Problem

To solve the problem, the present invention provides a bonded wafer production method for producing a bonded wafer having a thin film on a base wafer by forming an ion implanted layer in a bond wafer by implanting at least one of gas ion of a hydrogen ion and a rare gas ion from the surface of the bond wafer and, after directly bonding an ion implanted surface of the bond wafer and a surface of the base wafer together or bonding the ion implanted surface of the bond wafer and the surface of the base wafer together with an insulator film placed therebetween, delaminating the bond wafer at the ion implanted layer, wherein, as at least one of the bond wafer and the base wafer, an epitaxial wafer is used, and, as cleaning of the epitaxial wafer which is performed before the formation of an epitaxial layer, single wafer processing spin cleaning is performed.

With such a bonded wafer production method, since single wafer processing spin cleaning is performed as cleaning of a wafer on which epitaxial growth is to be performed, at the time of cleaning, it is possible to allow the wafer to make contact with a wafer support only in a region in which no epitaxial growth is performed. Thus, even when epitaxial growth is performed on the wafer, it is possible to avoid the growth of micro convex defects on a surface to be subjected to bonding. As a result, it is possible to produce a bonded wafer having a small terrace width all around the bonded wafer.

At this time, as the base wafer, the epitaxial wafer may be used.

As described above, the bonded wafer production method of the present invention can be particularly suitably used when an epitaxial wafer is used as a base wafer.

Moreover, the present invention provides a bonded wafer in which a thin film is directly bonded to a base wafer or is bonded to the base wafer with an insulator film placed therebetween, wherein the base wafer is an epitaxial wafer having an epitaxial layer, and, in a terrace portion which is a portion of an upper surface of the base wafer on the periphery thereof, the portion where no thin film is formed, an epitaxial defect which is a convex defect caused by the growth of the epitaxial layer is not present.

With such a bonded wafer, even when the bonded wafer is a bonded wafer using an epitaxial wafer as a base wafer, the bonded wafer can be provided as a bonded wafer with a small terrace width. Such a bonded wafer has a large effective area and therefore a portion thereof close to the outer circumferential edge can be used for device formation.

### Advantageous Effects of Invention

With the bonded wafer production method of the present invention, when an epitaxial wafer is used as one of a bond wafer and a base wafer, it is possible to produce a bonded wafer with a small terrace width. Moreover, with the bonded wafer of the present invention, a terrace portion does not spread in some regions, which makes it possible to provide a bonded wafer with a small terrace width. Such a bonded wafer has a large effective area and therefore a portion thereof close to the outer circumferential edge can be used for device formation.

### BRIEF DESCRIPTION OF DRAWINGS

FIG. 1 is a flow diagram depicting an example of a bonded wafer production method of the present invention; and

FIG. 2 is a photomicrograph of the periphery of a bonded SOI wafer (an existing bonded SOI wafer) in which an epitaxial wafer obtained by performing batch processing cleaning as cleaning before epitaxial growth is used as a base wafer.

### DESCRIPTION OF EMBODIMENTS

As described earlier, development of a bonded wafer production method by which a bonded wafer with a small terrace width can be produced even when an epitaxial wafer is used as a raw material wafer (at least one of a bond wafer and a base wafer) has been required.

As a result of the inventors of the present invention having conducted intensive studies about the above problem, the inventors of the present invention have found the following facts. In a method for producing an epitaxial wafer, as cleaning which is performed immediately before the formation of an epitaxial layer (which is also called simply “pre-epi cleaning”), in general, cleaning (batch processing cleaning) by which a plurality of wafers are set on a wafer carrier and immersed in a chemical solution is mainly used. If the batch processing cleaning is used as the pre-epi cleaning, a micro convex defect sometimes grows by epi-growth due to a contact mark or a foreign substance remaining in a portion of the wafer periphery where the wafer periphery made contact with the carrier and in an area surrounding the portion. However, since the defect generation region is an about 0.5-to-2-mm wide region from the wafer outer circumferential edge, this region corresponds to an outer circumferential exclusion region (a region which is not used for device fabrication) in a normal epitaxial wafer inspection process and is not regarded as a failure. However, if a wafer with such a micro convex defect is used as a raw material wafer (at least one of a bond wafer and a base wafer) for fabricating a bonded wafer by an ion implantation delamination method, a portion in which the convex defect is present cannot be bonded and the size of a terrace portion becomes larger as compared to the other regions, which is a problem newly found by the studies. In other words, it has been revealed that the use of an epitaxial wafer in the production of a bonded wafer causes a problem which would not arise if an epitaxial wafer is not used in the production of a bonded wafer.

FIG. 2 is a photomicrograph of the periphery of a bonded SOI wafer in which an epitaxial wafer obtained by performing the batch processing cleaning as the pre-epi cleaning is used as a base wafer. (a) of FIG. 2 is a photomicrograph of the periphery of the bonded SOI wafer taken from the SOI layer's side. In (a) of FIG. 2, a base wafer surface is present as a terrace portion, and, in many regions, the terrace portion with a nearly constant width is formed from the outer circumferential edge to the inside. Inside the terrace portion, the surface of a thin film (an SOI layer) is observed. On the right side of the area depicted in (a) of FIG. 2, a region judged to be a region in which a failure has occurred in the terrace portion is present. In this region, the terrace width is larger than that of the other regions (terrace deformation). This failure in the terrace portion is also called a “void defect”. In this failure portion, the micro convex defects described above are present. (b) of FIG. 2 is a photomicrograph of the enlarged micro convex defects. Flat pyramid-shaped micro convex defects (which are also referred to as “epitaxial defects”) observed in (b) of FIG. 2 are present near the edge portion of the wafer and become a cause of the terrace deformation.

The inventors of the present invention have further conducted intensive studies based on the above findings and found that, even when an epitaxial wafer is used as at least one of a bond wafer and a base wafer in a bonded wafer production method using an ion implantation delamination method, by performing single wafer processing spin cleaning as cleaning of the epitaxial wafer which is performed before the formation of an epitaxial layer, it is possible to prevent micro convex defects from being formed in a bonded region on the epitaxial wafer, which makes it possible to produce a bonded wafer with a small terrace width without allowing a terrace portion to spread in some regions, and have completed the present invention.

Hereinafter, the present invention will be described in detail, but the present invention is not limited to the following description.

First, a bond wafer and a base wafer are prepared.

Here, as at least one of the bond wafer and the base wafer, an epitaxial wafer is prepared. As the epitaxial wafer, for example, an epitaxial wafer obtained by growing an epitaxial layer on a mirror-polished silicon single crystal wafer can be used. Moreover, as the wafer on which epitaxial growth is not performed, a mirror-polished silicon single crystal wafer, for example, can be suitably used. In the present invention, single wafer processing spin cleaning is performed as cleaning (pre-epi cleaning) of the epitaxial wafer which is performed before the formation of an epitaxial layer. By performing the single wafer processing spin cleaning as the pre-epi cleaning, since it is possible to allow the wafer to make contact with a wafer support only in a region in which no epitaxial growth is performed, even when epitaxial growth is performed on the wafer subjected to cleaning, it is possible to avoid the growth of micro convex defects on a surface to be subjected to bonding.

The single wafer processing spin cleaning is known as one of the methods of cleaning a semiconductor wafer and is a cleaning method by which the metallic impurity level and the particle level on the semiconductor wafer surface can be reduced at the same time by performing, as described in, for example, Patent Document 2, cleaning having at least one cleaning process in which HF cleaning, ozone water cleaning, and HF cleaning are performed in this order. However, the combination of chemical solutions is not limited to this combination, and an appropriate combination can be adopted in accordance with the intended use. For instance, a combination of an SC1 cleaning solution (a mixed aqueous solution of NH₄OH and H₂O₂) and an SC2 cleaning solution (a mixed aqueous solution of HCl. and H₂O₂) can also be adopted.

Next, as an arbitrary step, an insulator film is formed on the surface of at least one of the bond wafer and the base wafer. The method for forming this insulator film is not limited to a particular method; for example, chemical vapor deposition (CVD) can be used, and, if the insulator film is an oxide film, a thermal oxidation method can also be used. If a bonded wafer is produced by directly bonding the bond wafer and the base wafer together without forming an insulator film, this insulator film is not formed.

Next, by implanting at least one of gas ion of a hydrogen ion and a rare gas ion from the surface of the bond wafer, an ion implanted layer is formed in the wafer. In so doing, an ion implantation acceleration voltage (acceleration energy) is selected so that a thin film having a desired film thickness can be obtained.

Next, the ion implanted surface of the bond wafer and the surface of the base wafer are directly bonded together or bonded together with the insulator film placed therebetween. Bonding can be performed at room temperature.

Next, by delaminating the bond wafer at the ion implanted layer, a bonded wafer having a thin film on the base wafer is produced. When the bond wafer is delaminated, it is necessary simply to delaminate the bond wafer by a publicly known method such as delamination heat treatment which is performed at about 400 to 600° C., for example. Moreover, by performing plasma processing in advance on at least one of the surfaces to be bonded together, the bond wafer can also be delaminated by applying an external force without performing heat treatment (or after performing heat treatment to the extent that the bond wafer is not delaminated).

In the bonded wafer production method of the present invention, it is necessary simply to perform the single wafer processing spin cleaning as the pre-epi cleaning, and the bonded wafer production method of the present invention may include various other steps in addition to those described above. For example, if necessary, cleaning may be performed before bonding or, after the delamination heat treatment, bonding heat treatment which enhances bonding strength may be performed at higher temperatures.

In the present invention, an epitaxial wafer can be used especially as a base wafer. As a result, the present invention can be applied to cases, whose number has recently increased as described earlier, in which even a foundation of a buried insulator film layer of an SOI wafer is separated by a trench or the like and used as part of a device structure.

Moreover, when an epitaxial wafer is used as a base wafer, the bonded wafer production method of the present invention can produce a bonded wafer in which a thin film is directly bonded to the base wafer or is bonded thereto with an insulator film placed therebetween, the bonded wafer in which the base wafer has an epitaxial layer. This bonded wafer can be provided as a bonded wafer in which, in a terrace portion which is a portion of the upper surface of the base wafer on the periphery thereof, the portion where no thin film is formed, an epitaxial defect which is a convex defect caused by the growth of the epitaxial layer is not present. Although this bonded wafer is a bonded wafer in which an epitaxial wafer is used as the base wafer, this bonded wafer can be provided as a bonded wafer with a small terrace width. Such a bonded wafer has a large effective area and therefore a portion thereof close to the outer circumferential edge can be used for device formation.

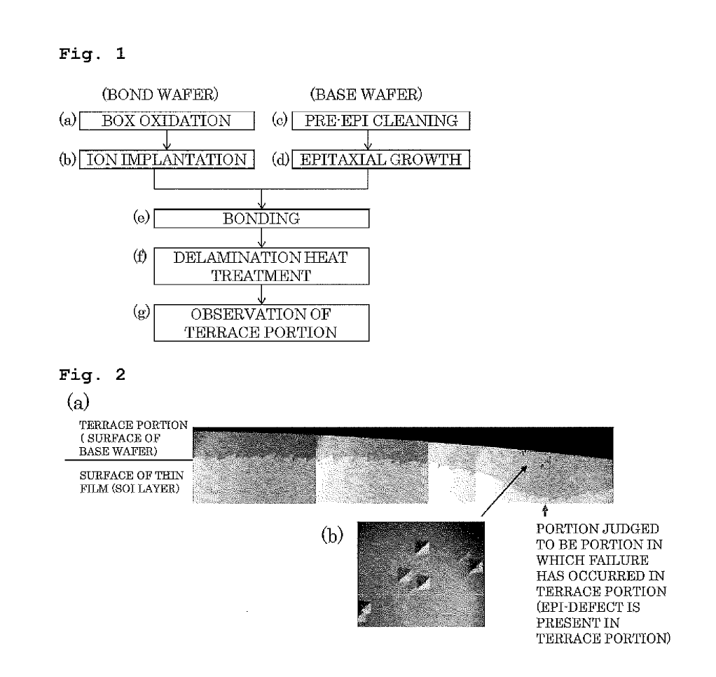

Hereinafter, the bonded wafer production method of the present invention will be described more specifically with reference to FIG. 1. FIG. 1 is a flow diagram depicting an example of the bonded wafer production method of the present invention, and, in this drawing, an example in which an SOI wafer is produced by forming an oxide film (an oxide film which becomes a buried oxide film (BOX) after bonding) on a bond wafer as an insulator film is depicted. Moreover, an example in which an epitaxial wafer is used only as a base wafer is depicted.

In the bonded wafer production method of FIG. 1, first, as depicted in (a) of FIG. 1, an oxide film is formed on the surface of a bond wafer as an insulator film (Step a). This oxide film is an oxide film which becomes a buried oxide film (BOX) after the bond wafer and a base wafer are bonded together. Thus, this step can be referred to as “BOX oxidation”. As described earlier, the method for forming this oxide film is not limited to a particular method, and a thermal oxidation method, CVD, or the like can be used.

Next, as depicted in (b) of FIG. 1, by implanting at least one of gas ion of a hydrogen ion and a rare gas ion from the surface of the bond wafer on which the oxide film is formed in the Step a, an ion implanted layer is formed in the wafer (Step b).

In addition to the processing (the Steps a and b) which is performed on the bond wafer to be bonded, a base wafer is prepared in the following manner.

Before epitaxial growth is performed on the base wafer (Step d), as depicted in (c) of FIG. 1, cleaning is performed (pre-epi cleaning, Step c). In the present invention, single wafer processing spin cleaning is performed as this pre-epi cleaning. As described earlier, by performing the single wafer processing spin cleaning as the pre-epi cleaning, since it is possible to allow the wafer to make contact with a wafer support only in a region in which no epitaxial growth is performed, even when epitaxial growth is performed, it is possible to avoid the growth of micro convex defects on a surface to be subjected to bonding.

Next, as depicted in (d) of FIG. 1, epitaxial growth is performed on the base wafer subjected to cleaning (epi-growth, Step d).

It is to be noted that the processes a and b may be performed before the processes c and d, and vice versa; alternatively, the processes a and b and the processes c and d can also be concurrently performed.

Next, as depicted in (e) of FIG. 1, the ion implanted surface of the bond wafer and the surface of the base wafer are bonded together with the oxide film formed on the bond wafer placed therebetween (Step e). Here, the surface of the base wafer to be bonded to the ion implanted surface of the bond wafer is a surface on which the epitaxial layer is formed.

Next, as depicted in (f) of FIG. 1, by performing delamination heat treatment, the bond wafer is delaminated at the ion implanted layer (Step f). As a result, it is possible to produce a bonded SOI wafer having a buried oxide film and a thin film (an SOI layer) on the base wafer.

Finally, as depicted in (g) of FIG. 1, by observing the terrace portion of the produced bonded SOI wafer, the state after bonding can be evaluated (Step g).

It is to be noted that, although Patent Document 3 describes, as a related art, performing epi-growth after performing HF spin cleaning, an object to be subjected to HF spin cleaning and epi-growth is an SOI wafer itself, which makes this related art different from the present invention.

### EXAMPLES

Hereinafter, the present invention will be described more specifically by using Examples and Comparative Example, but the present invention is not limited to these examples.

### Example 1

A bonded wafer was produced by the method described in FIG. 1.

First, as a bond wafer, a single crystal silicon wafer whose diameter was 300 mm, plane orientation was (100), conductivity type was p-type, and resistivity was 10 Ωcm was prepared. On the surface of this bond wafer, an oxide film which becomes a buried oxide film was formed by thermal oxidation so as to have a thickness of 200 nm (BOX oxidation, the Step a). Next, ion implantation was performed on this bond wafer. The ion implantation conditions were set as follows: an ion to be implanted was an H⁺ ion, an acceleration voltage was 48.7 keV, and the dose amount was 7.5×10¹⁶/cm².

Next, as a base wafer, an epitaxial wafer was prepared in the following manner. As a substrate for growth on which epitaxial growth is performed, a single crystal silicon wafer whose diameter was 300 mm, plane orientation was (100), conductivity type was n-type, and resistivity was 10 Ωcm was prepared. Next, single wafer processing spin cleaning was performed on this substrate for growth (the Step c). As the single wafer processing spin cleaning, a set of (1) ozone water cleaning (10 ppm, ordinary temperature, 15 seconds) and (2) HF aqueous solution cleaning (1 wt %, ordinary temperature, 15 seconds) was repeated twice (that is, (1), (2), (1), (2)).

Next, an epitaxial layer was grown on the substrate for growth (the Step d). In so doing, trichlorosilane was used as source gas and the growth conditions were set as follows: a growth temperature was 1100° C., a film thickness was 3.5 μm, a conductivity type was n-type (doped with phosphorus), and resistivity was 0.001 Ωcm. In this way, an epitaxial wafer was prepared as the base wafer.

Next, the bond wafer and the base wafer prepared as described above were bonded together (the Step e). Before bonding, both wafers were cleaned, and, after being cleaned, the wafers were bonded together at room temperature.

Next, the bond wafer bonded to the base wafer was delaminated at the ion implanted layer by delamination heat treatment (the Step f). The conditions of the delamination heat treatment were 500° C., 30 minutes, and an Ar atmosphere.

A bonded SOI wafer was produced in the manner described above. As evaluations of this bonded SOI wafer, the terrace width was measured by observing the wafer under a microscope (the Step g). If the terrace width of the wafer was 1.7 mm or less all around the wafer, the wafer was judged to be an accepted product. Moreover, a large number of wafers were produced under the same conditions and a failure rate was calculated. This failure rate was calculated from the ratio of the number of failures, which was the number of bonded SOI wafers whose terrace width was a failure, to the number of produced bonded SOI wafers.

### Example 2

A bonded SOI wafer was produced in the same manner as in Example 1 except that the method of pre-epi cleaning was changed. The cleaning method of pre-epi cleaning was the same as that of Example 1 in that the cleaning method was single wafer processing spin cleaning, but the combination of chemical solutions was changed to a combination of SC1 cleaning (70° C., 120 seconds) and SC2 cleaning (50° C., 120 seconds).

### Comparative Example

A bonded SOI wafer was produced in the same manner as in Example 2 except that the method of pre-epi cleaning was changed. As the cleaning method of the pre-epi cleaning, the batch processing cleaning using a wafer carrier was adopted. As chemical solutions used in the batch processing cleaning, as in the case of Example 2, a combination of SC1 cleaning (70° C., 120 seconds) and SC2 cleaning (50° C., 120 seconds) was adopted.

The implementation conditions of Examples 1 and 2 and Comparative Example and the evaluation results are shown in Table 1.

TABLE 1

| | | Comparative |
|---|---|---|
| | Examples 1 and 2 | Example |
| Bond wafer | Diameter 300 mm, (100), p-type, 10 Ωcm | |
| BOX | Thermal oxidation (oxide film thickness: 200 nm) | |
| oxidation | | |
| Ion | H⁺ ion, 48.7 keV, 7.5 × 10¹⁶/cm² | |
| implantation | | |
| Base wafer | Diameter 300 mm, (100), n-type, 10 Ωcm | |
| Pre-epi | Single wafer processing spin cleaning | Batch-type |
| cleaning | (Example 1) | cleaning (using |
| | (1) ozone water cleaning (10 | a wafer |
| | ppm, ordinary temperature, 15 | carrier) |
| | seconds) | (Comparative |
| | (2) HF aqueous solution | Example) |
| | cleaning (1 wt %, ordinary | SC1 cleaning |
| | temperature, 15 seconds) | (70° C., 120 |
| | *(1) + (2) is repeated twice | seconds) + |
| | (Example 2) | SC2 cleaning |
| | SC1 cleaning (70° C., 120 | (50° C., 120 |
| | seconds) + | seconds) |
| | SC2 cleaning (50° C., 120 | |
| | seconds) | |
| Epi-growth | [Growth conditions] | |
| | Growth temperature: 1100° C., film thickness: 3.5 μm | |
| | Conductivity type: n-type (doped with phosphorus), | |
| | resistivity: 0.001 Ωcm | |
| Bonding | Room temperature (pre-bonding cleaning is performed) | |
| Delamlnation | 500° C., 30 minutes, Ar atmosphere | |
| heat | | |
| treatment | | |
| Evaluation | The terrace width is measured by observing the | |
| method | wafer under a microscope. | |
| | A wafer whose terrace width is 1.7 mm or less | |
| | all around the wafer is judged to be an accepted product. | |
| Evaluation | Failure rate: | Failure rate: |
| results | (Example 1) 0.5%, | 20% |
| | (Example 2) 1% | |

Failure rate = The number of failures/the number of produced bonded SOI wafers × 100(%)

As shown in Table 1, in Examples 1 and 2 in which the single wafer processing spin cleaning was used as the pre-epi cleaning, the failure rates were 0.5% and 1%, respectively, and were much lower than the failure rate in Comparative Example, and the effect of the present invention could be obtained. In Comparative Example, although the same combination of chemical solutions as that of Example 2 was adopted, the failure rate was higher than the failure rate in Example 2 due to the use of the batch processing cleaning as the pre-epi cleaning.

It is to be understood that the present invention is not limited in any way by the embodiment thereof described above. The above embodiment is merely an example, and anything that has substantially the same structure as the technical idea recited in the claims of the present invention and that offers similar workings and benefits falls within the technical scope of the present invention.

What is claimed is:

1. A bonded wafer production method for producing a bonded wafer having a thin film on a base wafer by forming an ion implanted layer in a bond wafer by implanting at least one of gas ion of a hydrogen ion and a rare gas ion from a surface of the bond wafer and, after directly bonding an ion implanted surface of the bond wafer and a surface of the base wafer together or bonding the ion implanted surface of the bond wafer and the surface of the base wafer together with an insulator film placed therebetween, delaminating the bond wafer at the ion implanted layer,
wherein
as at least one of the bond wafer and the base wafer, an epitaxial wafer is used, and
as cleaning of the epitaxial wafer which is performed before a formation of an epitaxial layer, single wafer processing spin cleaning is performed.

2. The bonded wafer production method according to claim 1, wherein
as the base wafer, the epitaxial wafer is used.

3. A bonded wafer in which a thin film is directly bonded to a base wafer or is bonded to the base wafer with an insulator film placed therebetween, wherein
the base wafer is an epitaxial wafer having an epitaxial layer, and
in a terrace portion which is a portion of an upper surface of the base wafer on a periphery thereof, the portion where no thin film is formed, an epitaxial defect which is a convex defect caused by a growth of the epitaxial layer is not present.
